(19) United States
(12) Patent Application Publication
(10) Pub. No.: US 2013/0023071 A1
(43) Pub. Date: Jan. 24, 2013

(54) DONOR SUBSTRATE, METHOD OF MANUFACTURING A DONOR SUBSTRATE AND METHOD OF MANUFACTURING AN ORGANIC LIGHT EMITTING DISPLAY DEVICE USING A DONOR SUBSTRATE

(71) Applicant: Sok-Won Noh, Yongin-city (KR)

(72) Inventor: Sok-Won Noh, Yongin-city (KR)

(21) Appl. No.: 13/449,264

(22) Filed: Apr. 17, 2012

(30) Foreign Application Priority Data
Jul. 19, 2011 (KR) 10-2011-0071375

(51) Int. Cl. H01L 33/52; B32B 27/30; B32B 27/36; B32B 27/32

(52) U.S. Cl. 438/26; 428/523; 428/522; 427/58; 257/E31.117

(57) ABSTRACT

A donor substrate may include a base substrate, an expansion layer positioned on the base substrate, a light-to-heat conversion layer on the expansion layer, an insulation layer located on the light-to-heat conversion layer, and an organic transfer layer on the insulation layer. The donor substrate may effectively and uniformly transfer the organic transfer layer onto a display substrate of an organic light emitting display device.

### CROSS-REFERENCE TO RELATED APPLICATION

This application claims priority under 35 USC §119 to Korean Patent Application No. 10-2011-0071375 filed on Jul. 19, 2011 in the Korean Intellectual Property Office (KIPO), the content of which is herein incorporated by reference in its entirety.

### BACKGROUND

1. Field

Example embodiments of the present invention relate to donor substrates, methods of manufacturing the donor substrates, and methods of manufacturing organic light emitting display devices using the donor substrate.

2. Description of Related Art

Generally, a display substrate of an organic light emitting display (OLED) device includes a thin film transistor (TFT), a pixel electrode, an organic layer, and a common electrode sequentially disposed on a transparent substrate. The organic layer includes a light emitting layer for generating white light, red light, green light, or blue light, and the organic layer additionally includes a hole injection layer (HIL), a hole transfer layer (HTL), an electron transfer layer (ETL), an electron injection layer (EIL), etc.

The organic layer is typically formed by a laser induced thermal imaging (LITI) process in which an organic transfer layer of a donor substrate is transferred onto the pixel electrode of the display substrate by irradiating a laser beam onto the donor substrate after attaching the donor substrate to the display substrate. When the organic transfer layer of the donor substrate is transferred onto the display substrate by the laser induced thermal imaging process, the organic transfer layer may not be precisely transferred onto the pixel electrode, and thus the organic layer may not be uniformly formed on the display substrate because of a static electricity that is generated from a friction between the donor substrate and the display substrate. Therefore, light emitting characteristics of the organic light emitting layer may be deteriorated to thereby reduce a quality of an image displayed by the organic light emitting display device.

### SUMMARY

Example embodiments of the present invention are directed toward a donor substrate that effectively transfers an organic transfer layer onto a display substrate by reducing a static electricity between the donor substrate and the display substrate.

Example embodiments of the present invention are directed toward a method of manufacturing a donor substrate for transferring an organic transfer layer onto a display substrate by reducing a static electricity between the donor substrate and the display substrate.

Example embodiments of the present invention are directed toward a method of manufacturing an organic light emitting display device including a uniform organic layer pattern using a donor substrate that effectively transfers an organic layer onto a display substrate.

According to example embodiments, there is provided a donor substrate. The donor substrate may include a base substrate, an expansion layer on the base substrate, a light-to-heat conversion (LTHC) layer on the expansion layer, an insulation layer on the light-to-heat conversion layer, and an organic transfer layer on the insulation layer.

In example embodiments, the expansion layer may include a material having a thermal expansion coefficient that is substantially equal to or substantially greater than about 1.5×10⁻⁵/° C. The expansion layer may include a thermoplastic resin. For example, the expansion layer may include polystyrene, polymethyl acrylate, polyethyl acrylate, polypropyl acrylate, poly isopropyl acrylate, poly n-butyl acrylate, poly sec-butyl acrylate, poly isobutyl acrylate, poly tetra-butyl acrylate, polymethyl methacrylate, polyethyl methacrylate, poly n-butyl methacrylate, poly n-decyl methacrylate, polyvinyl chloride, polyvinylidene chloride, acrylonitrile-butadiene-styrene copolymer, etc.

In example embodiments, the base substrate may include a thermoplastic resin. In this case, the base substrate and the expansion layer may be integrally formed.

According to example embodiments, there is provided a donor substrate. The donor substrate may include a base substrate, a light-to-heat conversion layer on a first side of the base substrate, an insulation layer on the light-to-heat conversion layer, an organic transfer layer on the insulation layer, and an antistatic member on the base substrate, in the base substrate, or on the insulation layer.

In example embodiments, the antistatic member may include an antistatic agent substantially dispersed in the base substrate. For example, the antistatic agent may have a concentration between about 0.1 percent by weight and about 0.2 percent by weight based on a total weight of the base substrate.

In example embodiments, the antistatic agent may include a glycerin monomer stearate-based antistatic material, an amine-based antistatic material, a magnetic metal oxide, etc.

In example embodiments, the antistatic member may include an antistatic agent substantially dispersed in the insulation layer. Alternatively, the antistatic member may include a transparent conductive layer on a second side of the base substrate. In this case, the transparent conductive layer may include a conductive metal oxide or a high molecular weight conductive material. For example, the transparent conductive layer may include polyaniline, polypyrrole, polythiophene, polyethylene dioxythiophene, antimony tin oxide (ATO), indium tin oxide (ITO), indium zinc oxide (IZO), niobium oxide, zinc oxide, gallium oxide, tin oxide, indium oxide, etc.

According to example embodiments, there is provided a method of manufacturing a donor substrate. In the method, a base substrate may be prepared. An expansion layer may be formed on the base substrate. A light-to-heat conversion layer may be formed on the expansion layer. An insulation layer may be formed on the light-to-heat conversion layer. An organic transfer layer may be formed on the insulation layer.

In example embodiments, the expansion layer may be formed by coating a thermoplastic resin on the base substrate by a spin coating process, a slit coating process, a gravure coating process, etc.

In example embodiments, the expansion layer may be formed using a polyethylene terephthalate resin containing a thermoplastic resin.

In example embodiments, the expansion layer may be formed by a biaxial drawing process.

According to example embodiments, there is provided a method of manufacturing a donor substrate. In the method, a base substrate may be provided. A light-to-heat conversion layer may be formed on a first side of the base substrate. An insulation layer may be formed on the light-to-heat conversion layer. An organic transfer layer may be formed on the insulation layer. An antistatic member may be formed in the base substrate, in the insulation layer, or on a second side of the base substrate

In example embodiments, the antistatic member may be obtained by substantially dispersing an antistatic agent in the base substrate. Alternatively, the antistatic member may be obtained by substantially dispersing an antistatic agent in the insulation layer.

In example embodiments, the antistatic member may be obtained by forming a transparent conductive layer on the second side of the base substrate.

According to example embodiments, there is provided a method of manufacturing an organic light emitting display device. In the method, a lower electrode may be formed on a substrate. A pixel defining layer may be formed on the lower electrode to define a pixel region of the organic light emitting display device. A donor substrate including a base substrate, an expansion layer, a light-to-heat conversion layer, and an organic transfer layer may be provided. The donor substrate may be attached to the substrate with the organic transfer layer substantially facing the pixel region of the substrate. An organic layer pattern may be formed on the pixel region from the organic transfer layer by irradiating a laser beam onto a portion of the donor substrate that is substantially opposite the pixel region.

In example embodiments, the donor substrate may additionally include an insulation layer between the light-to-heat conversion layer and the organic transfer layer.

According to example embodiments, there is provided a method of manufacturing an organic light emitting display device. In the method, a lower electrode may be formed on a substrate. A pixel defining layer may be formed on the lower electrode to define a pixel region. A donor substrate having a base substrate, a light-to-heat conversion layer on a first side of the base substrate, an insulation layer, and an organic transfer layer may be prepared. An antistatic member may be formed in the base substrate, in the insulation layer, or on a second side of the base substrate. The donor substrate may be attached to the substrate with the organic transfer layer substantially facing the pixel region of the substrate. An organic layer pattern may be formed on the pixel region from the organic transfer layer by irradiating a laser beam onto the donor substrate that is substantially opposite the pixel region.

In example embodiments, the antistatic member may include an antistatic agent substantially dispersed in the insulation layer or in the base substrate.

According to example embodiments, the donor substrate may include the expansion layer, so that the organic transfer layer of the donor substrate may be effectively separated from the donor substrate to thereby easily form the organic layer pattern on a display substrate. Additionally, the organic layer pattern may be efficiently formed on the display substrate by irradiating a laser beam having a relatively low energy onto the donor substrate. According to some example embodiments, the donor substrate may include the antistatic member having the antistatic agent, the antistatic layer, and/or the transparent conductive layer, such that the donor substrate may prevent or reduce a static electricity that is generated between the donor substrate and the display substrate while transferring the organic transfer layer onto the display substrate. Therefore, the organic layer pattern may be uniformly formed on the display substrate from the organic transfer layer of the donor substrate. As a result, the organic layer pattern may ensure improved light emitting characteristics, and thus the organic light emitting display device may have enhanced image quality.

### BRIEF DESCRIPTION OF THE DRAWINGS

Example embodiments of the present invention will be more clearly understood from the following detailed description taken in conjunction with the accompanying drawings. FIGS. 1 to 7 represent non-limiting, example embodiments as described herein.

FIG. 1 is a cross-sectional view illustrating a donor substrate in accordance with example embodiments.

FIG. 2 is a cross-sectional view illustrating a donor substrate in accordance with some example embodiments.

FIG. 3 is a cross-sectional view illustrating a donor substrate in accordance with some example embodiments.

FIG. 4 is a cross-sectional view illustrating a donor substrate in accordance with some example embodiments.

FIGS. 5 to 7 are cross-sectional views illustrating a method of manufacturing an organic light emitting display device in accordance with example embodiments.

### DETAILED DESCRIPTION OF EMBODIMENTS

Example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to,” or “coupled to” another element or layer, it can be directly on, connected, or coupled to the other element or layer, or one or more intervening elements or layers may be present. When an element is referred to as being “directly on,” “directly connected to,” or “directly coupled to” another element or layer, there may be no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below may be termed as a second element, component, region, layer, or section without departing from the teachings of the invention.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. For example, the term “below” can encompass both an orientation of above and below. The device may be otherwise oriented (rotated 90 degrees or at other orientations), and the spatially relative descriptors used herein are interpreted accordingly.

The terminology used herein is for the purpose of describing particular example embodiments only and is not intended to limit the invention thereto. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

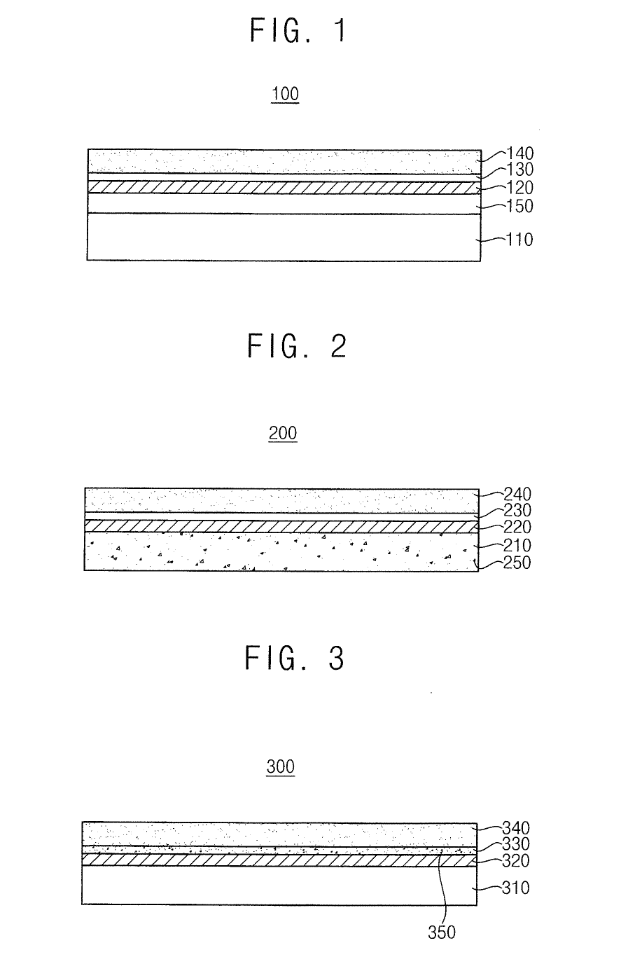

FIG. 1 is a cross-sectional view illustrating a donor substrate in accordance with example embodiments.

Referring to FIG. 1, a donor substrate 100 may include a base substrate 110, an expansion layer 150, a light-to-heat conversion (LTHC) layer 120, an insulation layer 130, an organic transfer layer 140, etc.

The base substrate 110 may transmit a laser beam to the light-to-heat conversion layer 120 in a laser induced thermal imaging (LITI) process for forming organic layer patterns on a display substrate of an organic light emitting display device. The base substrate 110 may include a substantially transparent material having a set or predetermined mechanical strength. For example, the base substrate 110 may include a transparent resin substrate, a glass substrate, a quartz substrate, etc. The transparent resin substrate may include a polyethylene terephthalate-based resin, a polyacryl-based resin, a polyepoxy-based resin, a polyethylene-based resin, a polystyrene-based resin, a polyimide-based resin, a polycarbonate-based resin, a polyether-based resin, a polyacrylate-based resin, etc.

The expansion layer 150 may be disposed on the base substrate 110. A portion of the expansion layer 150 heated by an irradiation of the laser beam may expand in the laser induced thermal imaging process. That is, a volume of the expansion layer 150 may at least partially increase by an irradiation of the laser beam in the laser induced thermal imaging process. The organic transfer layer 140 may be effectively separated from the base substrate 110 by an expansion of the expansion layer 150, so that organic layer patterns may be efficiently formed on the display substrate of the organic light emitting display device using the organic transfer layer 140 of the donor substrate 100. In example embodiments, the expansion layer 150 may include a material having a relatively high expansion coefficient. In this case, the expansion layer 150 may include a material having a thermal expansion coefficient substantially equal to or substantially greater than about 1.5×10⁻⁵/° C. For example, the expansion layer 150 may include a thermoplastic resin having a relatively large thermal expansion coefficient. Examples of the thermoplastic resin in the expansion layer 150 may include a low molecular weight thermoplastic polymer such as polystyrene, polymethyl acrylate, polyethyl acrylate, polypropyl acrylate, poly n-butyl acrylate, poly sec-butyl acrylate, poly isobutyl acrylate, poly tetra-butyl acrylate, polymethyl methacrylate, polyethyl methacrylate, poly n-butyl methacrylate, poly n-decyl methacrylate, polyvinyl chloride, polyvinylidene chloride, acrylonitrile-butadiene-styrene copolymer, etc.

The light-to-heat conversion layer 120 may be disposed on the expansion layer 150. The light-to-heat conversion layer 120 may absorb the laser beam irradiated through the base substrate 110, and then the light-to-heat conversion layer 120 may convert energy of the laser beam to heat or thermal energy. The light-to-heat conversion layer 120 may include a metal, a metal oxide, a metal sulfide, a material containing carbon, etc. For example, the light-to-heat conversion layer 120 may include a metal such as aluminum (Al), nickel (Ni), molybdenum (Mo), titanium (Ti), zirconium (Zr), copper (Cu), vanadium (V), tantalum (Ta), palladium (Pd), ruthenium (Ru), iridium (Ir), gold (Au), silver (Ag), or platinum (Pt), metal oxides thereof, metal sulfides thereof, carbon black, graphite, etc. These may be used alone or in a combination thereof.

The insulation layer 130 may be disposed on the light-to-heat conversion layer 120. The insulation layer 130 may prevent the organic transfer layer 140 from being contaminated or being damaged. Further, the insulation layer 130 may adjust an adhesion strength between the light-to-heat conversion layer 120 and the organic transfer layer 140 in the laser induced thermal imaging process, such that the insulation layer 130 may improve a uniformity of the organic layer patterns formed on the display substrate. In example embodiments, the insulation layer 130 may include an organic material or an inorganic material. For example, the insulation layer 130 may include an acrylic resin, an alkyd resin, silicon oxide (SiOx), aluminum oxide (AlOx), magnesium oxide (MgOx), etc. The organic transfer layer 140 may be disposed on the insulation layer 130.

The organic transfer layer 140 may be separated from the donor substrate 100 by the thermal energy or the heat transferred from the light-to-heat conversion layer 120 to form the organic layer patterns on the display substrate. In example embodiments, the organic transfer layer 140 may include an organic light emitting layer that generates red light, green light, or blue light. In some example embodiments, the organic transfer layer 140 may additionally include a hole injection layer (HIL), a hole transferring layer (HTL), an electron transferring layer (ETL), an electron injection layer (EIL), etc. In this case, the organic light emitting layer of the organic transfer layer 140 may have a multi-layer structure for generating all of red light, green light, and blue light to obtain white light.

In example embodiments, when the organic light emitting layer of the organic transfer layer 140 generates red light, the organic light emitting layer may include a low molecular weight material such as Alq3, Alq3 (host)/DCJTB (fluorescence dopant), Alq3 (host)/DCM (fluorescence dopant), or CBP (host)/PtOEP (phosphorescent organic metal complex), and a high molecular weight material such as a PFO-based high molecular weight material or a PPV-based high molecular weight material, which may generate a red light. When the organic light emitting layer generates green light, the organic light emitting layer may include a low molecular weight material such as Alq3, Alq3 (host)/C545t (dopant), or CBP (host)/IrPPy (phosphorescent organic metal complex), and a high molecular weight material such as a PFO-based high molecular weight material or a PPV-based high molecular weight material, which may generate green light. In the case that the organic light emitting layer generates blue light, the organic light emitting layer may include a low molecular weight material such as DPVBi, spiro-DPVBi, spiro-6P, DSB, or DSA, and a high molecular weight material such as a PFO-based high molecular weight material or a PPV-based high molecular weight material, which may generate blue light.

The hole injection layer of the organic transfer layer 140 may include a low molecular weight material such as CuPc, TNATA, TCTA, or TDAPB, and a high molecular weight material such as PANI or PEDOT. The hole transfer layer of the organic transfer layer 140 may include a low molecular weight material such as a arylamine-based low molecular weight material, a hydrazone-based low molecular weight material, a stilbene-based low molecular weight material, or a starburst-based low molecular weight material, or a high molecular weight material such as a carbazole-based high molecular weight material, a arylamine-based high molecular weight material, a perylene-based high molecular weight material, or a pyrrole-based high molecular weight material.

The electron transfer layer of the organic transfer layer 140 may include a low molecular weight material such as Alq3, BAlq, or SAlq, or a high molecular weight material such as PBD, TAZ, or spiro-PBD. Additionally, the electron injection layer of the organic transfer layer 140 may include a low molecular weight material such as Alq3, gallium complex, or PBD, or a high molecular weight material, e.g., an oxadiazol-based high molecular weight material.

In some example embodiments, a gas generation layer and/or a metal reflection layer may be additionally provided between the insulation layer 130 and the organic transfer layer 140. In this case, the gas generation layer may generate a nitrogen gas or a hydrogen gas in accordance with a decomposition reaction caused by absorbing energy of light or heat to thereby provide a transfer energy to the organic transfer layer 140. For example, the gas generation layer may include pentaerythritol tetranitrate, trinitrotoluene, etc. The metal reflection layer may reflect the laser beam irradiated onto the donor substrate 100 to thereby transfer more energy to the light-to-heat conversion layer 120, and also the metal reflection layer may prevent a gas generated from the gas generation layer from permeating to the organic transfer layer 140. For example, the metal reflection layer may include a metal having a relatively high reflectivity such as aluminum (Al), molybdenum (Mo), titanium (Ti), silver (Ag), platinum (Pt), etc.

In example embodiments, the donor substrate 100 may include the expansion layer 150, such that the expansion layer 150 may partially expand by the irradiation of the laser beam in the laser induced thermal imaging process. That is, a portion of the expansion layer 150 positioned under the organic transfer layer 140 may expand in the laser induced thermal imaging process. Accordingly, a distance between the organic transfer layer 140 of the donor substrate 100 and a display region of the display substrate on which the organic transfer layer 140 is transferred, may be reduced. As a result, the organic transfer layer 140 may be effectively transferred from the donor substrate 100 to the display substrate, and the organic layer patterns may be uniformly formed on the display substrate.

Hereinafter, there will be described a method of manufacturing a donor substrate having a construction that is substantially the same as or substantially similar to that of the donor substrate 100 described with reference to FIG. 1.

In example embodiments, a base substrate 110 may be prepared, and then an expansion layer 150 may be formed on the base substrate 110. The base substrate 110 may include a transparent substrate, for example, a transparent resin substrate, a glass substrate, a quartz substrate, etc. For example, the base substrate 110 may include a transparent resin substrate including polyethylene terephthalate (PET), polyacryl, polyepoxy, polyethylene, polystyrene, polyimide, polycarbonate, polyether, polyacrylate, etc.

The expansion layer 150 may be formed using a thermoplastic resin having a relatively large thermal expansion coefficient. Thus, when the laser beam is irradiated onto the expansion layer 150, the expansion layer 150 may be partially or entirely expanded. For example, the expansion layer 150 may be formed using a low molecular weight thermoplastic polymer having a thermal expansion coefficient substantially equal to or substantially greater than about 1.5×10⁻⁵/° C. In this case, the expansion layer 150 may be formed using polystyrene, polymethyl acrylate, polyethyl acrylate, polypropyl acrylate, poly isopropyl acrylate, poly n-butyl acrylate, poly sec-butyl acrylate, poly isobutyl acrylate, poly tert-butyl acrylate, polymethyl methacrylate, polyethyl methacrylate, poly n-butyl methacrylate, poly n-decyl methacrylate, poly vinyl chloride, poly vinylidene chloride, acrylonitrile-butadiene-styrene copolymer, etc. Additionally, the expansion layer 150 may be formed on the base substrate 110 by a spin coating process, a slit coating process, a gravure coating process, etc.

In some example embodiments, the expansion layer 150 may be formed as a polyethylene terephthalate film including a thermoplastic resin. In a process for forming the polyethylene terephthalate film, a polyethylene terephthalate resin may be obtained by a condensation polymerization reaction, and then the polyethylene terephthalate resin having an arbitrary shape may be cut by a melt extruding process to form a polyethylene terephthalate chip. The polyethylene terephthalate film may be obtained by performing a biaxial drawing process about the polyethylene terephthalate chip. In some example embodiments, after preparing a polyethylene terephthalate resin by a condensation polymerization reaction, a thermoplastic resin may be added to the polyethylene terephthalate resin with a predetermined concentration to obtain a polyethylene terephthalate chip including the thermoplastic resin. By performing a biaxial drawing process about the polyethylene terephthalate chip including the thermoplastic resin, the expansion layer 150 including the polyethylene terephthalate film may be obtained with improved thermal expansion characteristics. In this case, the expansion layer 150 including the polyethylene terephthalate film containing the thermoplastic resin may have a thermal expansion coefficient more than five times larger than that of an expansion layer which does not include a thermoplastic resin.

In some example embodiments, the expansion layer 150 and the base substrate 110 may be integrally formed when the expansion layer 150 includes the polyethylene terephthalate film containing the thermoplastic resin, and the base substrate 110 includes polyethylene terephthalate.

A light-to-heat conversion layer 120 may be formed on the expansion layer 150. The light-to-heat conversion layer 120 may be formed using a metal, a metal oxide, a metal sulfide, etc. For example, the light-to-heat conversion layer 120 may be formed using a metal such as aluminum (Al), nickel (Ni), molybdenum (Mo), titanium (Ti), zirconium (Zr), copper (Co), vanadium (V), tantalum (Ta), palladium (Pa), ruthenium (Ru), iridium (Ir), gold (Au), silver (Ag), or platinum (Pt), metal oxides thereof, metal sulfides thereof, etc. Further, the light-to-heat conversion layer 120 may be formed on the expansion layer 150 by a vacuum evaporation process, an e-beam deposition process, a sputtering process, etc. In some example embodiments, the light-to-heat conversion layer 120 may be formed using an organic material including a high molecular weight material containing carbon black, graphite, or an infrared light dye. In this case, the light-to-heat conversion layer 120 may be formed on the expansion layer 150 by a roll coating process, a gravure coating process, a spin coating process, a slit coating process, etc.

An insulation layer 130 may be formed on the light-to-heat conversion layer 120. The insulation layer 130 may be formed using an organic material or an inorganic material. For example, the insulation layer 130 may be formed using an acryl resin, an alkyd resin, silicon oxide, aluminum oxide, magnesium oxide, etc. When the insulation layer 130 includes the organic material, the insulation layer 130 may be formed on the light-to-heat conversion layer 120 by a coating process and an ultraviolet (UV) curing process. In the case that the insulation layer 130 includes a metal oxide, the insulation layer 130 may be formed on the light-to-heat conversion layer 120 by a vacuum evaporation process, an e-beam deposition process, a sputtering process, a chemical vapor deposition (CVD) process, etc.

An organic transfer layer 140 may be formed on the insulation layer 130. Thus, the donor substrate may include the base substrate 110, the expansion layer 150, the light-to-heat conversion layer 120, the insulation layer 130, and the organic transfer layer 140. The organic transfer layer 140 may include an organic light emitting layer, a hole injection layer, a hole transfer layer, an electron injection layer, an electron transfer layer, etc. Here, elements of the organic transfer layer 140 may be formed using various materials in accordance with colors of light generated by the organic transfer layer 140. Additionally, the organic transfer layer 140 may be formed on the insulation layer 130 by a spin coating process, a slit coating process, a roll coating process, a gravure coating process, a vacuum evaporation process, a chemical vapor deposition process, etc.

FIG. 2 is a cross-sectional view illustrating a donor substrate 200 in accordance with some example embodiments. In the donor substrate 200 illustrated in FIG. 2, a light-to-heat conversion layer 220, an insulation layer 230, and an organic transfer layer 240 may be substantially the same as or substantially similar to the light-to-heat conversion layer 120, the insulation layer 130, and the organic transfer layer 140 described with reference to FIG. 1.

Referring to FIG. 2, the donor substrate 200 may include a base substrate 210 including an antistatic agent 250 as an antistatic member, the light-to-heat conversion layer 220, the insulation layer 230, the organic transfer layer 240, etc.

The base substrate 210 may include a transparent substrate having the antistatic agent 250. For example, the transparent substrate may include polyethylene terephthalate, polyacryl, polyepoxy, polyethylene, polystyrene, polyimide, polycarbonate, polyether, polyacrylate, etc. In some example embodiments, the antistatic member 250 may include an antistatic layer (not illustrated) disposed between the base substrate 210 and the light-to-heat conversion layer 220. In some example embodiments, the light-to-heat conversion layer 220 may be on a first side of the base substrate 210, and an antistatic layer may be on a second side of the base substrate 210. Here, the first side of the base substrate 210 may be substantially opposite the second side of the base substrate 210.

In example embodiments, the antistatic agent 250 or the antistatic layer may include an amine-based antistatic material containing polyethylene alkylamine, a glycerin monomer stearate-based antistatic material, a mixture of a glycerin monomer stearate-based antistatic material and an amine-based antistatic material, etc. In some example embodiments, the antistatic agent 250 in the base substrate 210 or the antistatic layer on the base substrate 210 may include a commercial antistatic material such as an antistatic additive FC-4400 manufactured by 3M® Company. (3M is a registered trademark in the United States). In some example embodiments, the antistatic agent 250 or the antistatic layer may include a sulfonate-based compound, a sulfate-based compound, a phosphate-based compound, a mixture thereof, etc. For example, the antistatic agent 250 or the antistatic layer may include alkyl sulfonate, alkyl benzene sulfonate, alkyl sulphate, alkyl phosphate, etc. In some example embodiments, the antistatic agent 250 in the base substrate 210 or the antistatic layer on the base substrate 210 may include a magnetic metal oxide such as iron oxide containing Fe₂O₃, FeO, etc.

The light-to-heat conversion layer 220 may be disposed on the base substrate 210 including the antistatic agent 250. In example embodiments, the antistatic layer may be disposed between the base substrate 210 and the light-to-heat conversion layer 220 instead of the antistatic agent 250. In some example embodiments, the light-to-heat conversion layer 220 and the antistatic layer may be disposed on opposite sides of the base substrate 210, respectively. That is, the light-to-heat conversion layer 220 and the antistatic layer may be spaced apart by the base substrate 210. The light-to-heat conversion layer 220 may include a metal, a metal oxide, a metal sulfide, or an organic material including a high molecular weight material containing carbon black, graphite, or an infrared light dye.

The insulation layer 230 may be disposed on the light-to-heat conversion layer 220. The insulation layer 230 may include an organic insulation material such as an acryl resin or an alkyd resin, or a metal oxide such as silicon oxide, aluminum oxide, magnesium oxide, etc.

The organic transfer layer 240 may be disposed on the insulation layer 230. The organic transfer layer 240 may include an organic light emitting layer, a hole injection layer, a hole transfer layer, an electron injection layer, an electron transfer layer, etc. Colors of light generated from organic layer patterns obtained from the organic transfer layer 240 may vary in accordance with ingredients of the organic transfer layer 240.

When organic layer patterns are formed on a display substrate of an organic light emitting display device using a conventional donor substrate, a static electricity may be generated by the donor substrate in a laser induced thermal imaging process. To remove or reduce the static electricity, a plurality of ionizers are installed in a chamber in which the laser induced thermal imaging process is carried out. However, the plurality of ionizers may increase the manufacturing costs of the organic light emitting display device. Further, the static electricity may not be effectively removed from the donor substrate when the inside of the chamber is maintained in a vacuum state or the inside of the chamber is filled with a nitrogen gas while forming the organic layer patterns. In example embodiments, the donor substrate 200 may include the base substrate 210 having the antistatic agent 250 and/or the antistatic layer as the antistatic member, so that the donor substrate 200 may prevent or effectively reduce a generation of static electricity in a laser induced thermal imaging process for forming the organic layer patterns of the organic light emitting display device. Accordingly, the organic layer patterns may be uniformly formed on a display substrate of the organic light emitting display device from the organic transfer layer 240 of the donor substrate 200. As a result, the organic layer patterns may have improved light emitting characteristics, and the organic light emitting display device may have enhanced image quality.

Hereinafter, there will be described a method of manufacturing a donor substrate having a construction that is substantially the same as or substantially similar to that of the donor substrate 200 described with reference to FIG. 2.

In example embodiments, while preparing a base substrate 210, an antistatic member including an antistatic agent 250 may be added in the base substrate 210. The antistatic agent 250 may include an amine-based antistatic agent, a glycerin monomer stearate-based antistatic agent, or a mixture of the amine-based antistatic agent and the glycerin monomer stearate-based antistatic agent. In some example embodiments, an antistatic member including an antistatic layer may be formed on a first side of the base substrate 210 (e.g., an upper side of the base substrate 210) or a second side of the base substrate 210 (e.g., a lower side of the base substrate 210).

When the antistatic agent 250 is dispersed in the base substrate 210, the antistatic agent 250 may be mixed with a transparent resin of the base substrate 210, and then a biaxial drawing process may be performed using the mixture of the antistatic agent 250 and the transparent resin to obtain the base substrate 210 including the antistatic agent 250 uniformly dispersed therein. In this case, the antistatic agent 250 in the base substrate 210 may have a concentration between about 0.1 percent by weight and about 0.2 percent by weight based on a total weight of the base substrate 210. For example, when the base substrate 210 includes a polyethylene terephthalate resin, the concentration of the antistatic agent 250 may be between about 0.1 percent by weight and about 0.2 percent by weight based on a total weight of the base substrate 210. In the case that the base substrate 210 includes a polypropylene resin, the concentration of the antistatic agent 250 may be between about 0.5 percent by weight and about 1.0 percent by weight based on a total weight of the base substrate 210. When the base substrate 210 includes a polystyrene resin, the antistatic agent 250 may have a concentration between about 1.0 percent by weight and about 1.5 percent by weight based on a total weight of the base substrate 210.

A light-to-heat conversion layer 220 may be formed on the base substrate 210. When the base substrate 210 includes the antistatic agent 250, or an antistatic layer is formed on a second side of the base substrate 210, the light-to-heat conversion layer 220 may be formed on a first side of the base substrate 210. Alternatively, the antistatic layer may be disposed on the first side of the base substrate 210, and the light-to-heat conversion layer 220 may be formed on the antistatic layer.

The light-to-heat conversion layer 220 may be formed by depositing a metal, a metal oxide, or a metal sulfide on the base substrate 210 by a vacuum evaporation process, an e-beam deposition process, a sputtering process, etc. In some example embodiments, the light-to-heat conversion layer 220 may be formed by depositing an organic material including a high molecular weight material containing carbon black, graphite, or an infrared light dye on the base substrate 210 by a roll coating process, a gravure coating process, a spin coating process, a slit coating process, etc.

The insulation layer 230 may be formed on the light-to-heat conversion layer 220. The insulation layer 230 may be formed using an organic insulation material or a metal oxide. When the insulation layer 230 includes an organic insulation material, the insulation layer 230 may be formed by a coating process and an ultraviolet (UV) curing process. When the insulation layer 230 includes a metal oxide, the insulation layer 230 may be formed on the light-to-heat conversion layer 220 by a vacuum evaporation process, an e-beam deposition process, a sputtering process, a chemical vapor deposition process, etc.

An organic transfer layer 240 may be formed on the insulation layer 230. The organic transfer layer 240 may have a multi-layer structure that includes an organic light emitting layer, a hole injection layer, a hole transfer layer, an electron injection layer, an electron transfer layer, etc. The organic transfer layer 240 may be formed on the insulation layer 230 by a spin coating process, a slit coating process, a roll coating process, a gravure coating process, a vacuum evaporation process, a chemical vapor deposition process, etc.

FIG. 3 is a cross-sectional view illustrating a donor substrate 300 in accordance with some example embodiments. In the donor substrate 300 illustrated in FIG. 3, a light-to-heat conversion layer 320, an insulation layer 330, and an organic transfer layer 340 may be substantially the same as or substantially similar to the light-to-heat conversion layer 220, the insulation layer 230, and the organic transfer layer 240 described with reference FIG. 2.

Referring to FIG. 3, the donor substrate 300 may include a base substrate 310, the light-to-heat conversion layer 320, the insulation layer 330 having an antistatic member, and the organic transfer layer 340. The antistatic member may include an antistatic agent 350. In some example embodiments, the donor substrate 300 may include an antistatic member having an antistatic layer (not illustrated) disposed between the light-to-heat conversion layer 320 and the insulation layer 330, or between the insulation layer 330 and the organic transfer layer 340.

The base substrate 310 may include a transparent substrate, for example, a transparent resin substrate, a glass substrate, a quartz substrate, etc. The transparent resin substrate may include a polyethylene terephthalate-based resin, a polyacryl-based resin, a polyepoxy-based resin, a polyethylene-based resin, a polystyrene-based resin, a polyimide-based resin, a polycarbonate-based resin, a polyether-based resin, a polyacrylate-based resin, etc. The light-to-heat conversion layer 320 may be disposed on the base substrate 310. The light-to-heat conversion layer 320 may include a metal, a metal oxide, a metal sulfide, a material containing carbon, etc.

The insulation layer 330 may be disposed on the light-to-heat conversion layer 320. When the antistatic layer is disposed on the light-to-heat conversion layer 320, the insulation layer 330 may include an organic insulation material such as an acryl resin or an alkyd resin, or a metal oxide such as silicon oxide, aluminum oxide, magnesium oxide, etc. In example embodiments, the antistatic agent 350 may be uniformly dispersed into the insulation layer 330. In this case, the antistatic agent 350 in the insulation layer 330 may have a concentration between about 0.1 percent by weight and about 2.0 percent by weight based on a total weight of the insulation layer 330. In some example embodiments, the antistatic layer may be disposed between the light-to-heat conversion layer 320 and the insulation layer 330, or on the insulation layer 330. The antistatic agent 350 or the antistatic layer may include an amine-based antistatic agent, a glycerin monomer stearate-based antistatic agent, or a mixture of the amine-based antistatic agent and the glycerin monomer stearate-based antistatic agent. In some example embodiments, the antistatic agent 350 or the antistatic layer may include a sulfonate-based compound, a sulfate-based compound, a phosphate-based compound, a mixture thereof, etc. In some example embodiments, the antistatic agent 350 or the antistatic layer may include a magnetic metal oxide such as iron oxide containing Fe₂O₃, FeO, etc.

The organic transfer layer 340 may be disposed on the insulation layer 330 or the antistatic layer. The organic transfer layer 340 may include a material that is substantially the same as or substantially similar to that of the organic transfer layer 140 of the donor substrate 100 described with reference to FIG. 1.

In example embodiments, the donor substrate 300 includes the insulation layer 330 having the antistatic agent 350 or the antistatic layer disposed on the insulation layer 330, so that the donor substrate 300 may prevent or considerably reduce a generation of a static electricity in a laser induced thermal imaging process for forming organic layer patterns on a display substrate of an organic light emitting display device. Accordingly, manufacturing costs for the organic light emitting display device may decrease because an additional antistatic device may not be used, and the organic layer patterns may be uniformly formed on the display substrate from the organic transfer layer 340 of the donor substrate 300. Therefore, light emitting characteristics of the organic layer patterns may be improved, and quality of an image displayed by the organic light emitting display device may be enhanced.

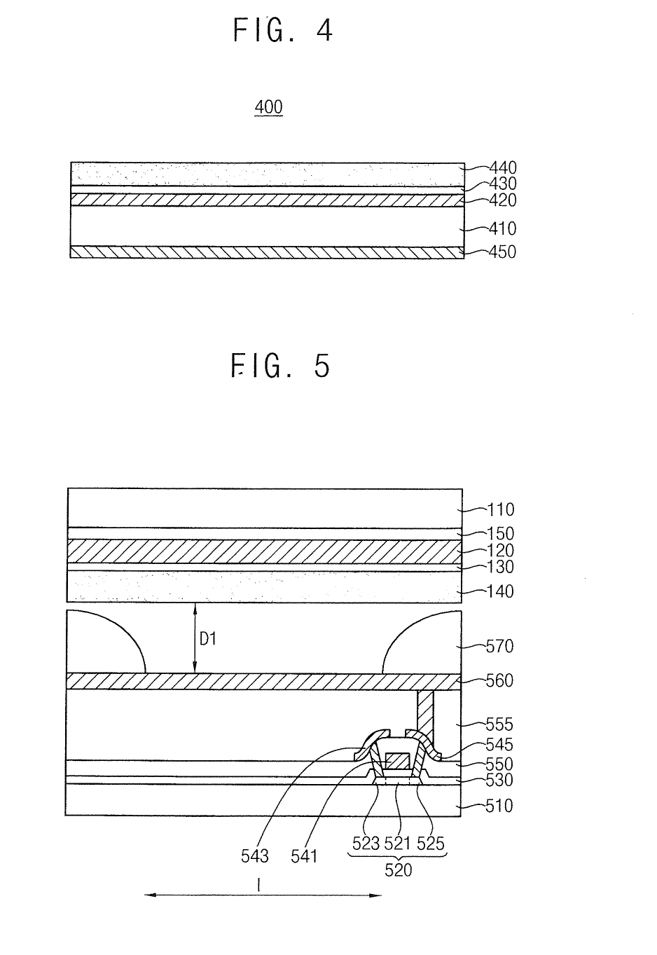

FIG. 4 is a cross-sectional view illustrating a donor substrate 400 in accordance with some example embodiments. In the donor substrate 400 illustrated in FIG. 4, a base substrate 410, a light-to-heat conversion layer 420, an insulation layer 430, and an organic transfer layer 440 may be substantially the same as or substantially similar to the base substrate 310, the light-to-heat conversion layer 320, the insulation layer 330, and the organic transfer layer 340 described with reference to FIG. 3.

Referring to FIG. 4, the donor substrate 400 may include the base substrate 410, the light-to-heat conversion layer 420, the insulation layer 430, the organic transfer layer 440, an antistatic member having a transparent conductive layer 450, etc.

The base substrate 410 may include a transparent substrate such as a transparent resin substrate, a glass substrate, a quartz substrate, etc. The light-to-heat conversion layer 420 may be disposed on a first side of the base substrate 410. For example, the light-to-heat conversion layer 420 may include a metal, a metal oxide, a metal sulfide, a material containing carbon, etc.

The insulation layer 430 may be disposed on the light-to-heat conversion layer 420. The insulation layer 430 may include an organic insulation material such as an acryl resin or an alkyd resin, or a metal oxide such as silicon oxide, aluminum oxide, magnesium oxide, etc. The organic transfer layer 440 may be disposed on the insulation layer 430. The organic transfer layer 440 may have an organic light emitting layer, a hole injection layer, a hole transfer layer, an electron injection layer, an electron transfer layer, etc.

In example embodiments, the antistatic member having the transparent conductive layer 450 may be disposed on a second side of the base substrate 410. In this case, the first side of the base substrate 410 and the second side of the base substrate 410 may be substantially opposite to each other. That is, the transparent conductive layer 450 and the light-to-heat conversion layer 420 may be disposed on opposite sides of the base substrate 410, respectively.

The transparent conductive layer 450 may include a transparent conductive metal oxide or a conductive high molecular weight material for transmitting a laser beam in a laser induced thermal imaging process. For example, the transparent conductive layer 450 may include a transparent conductive high molecular weight material such as polyaniline, polypyrrole, polythiophene, poly(3,4-ethylenedioxythiophene), etc. In some example embodiments, the transparent conductive layer 450 may include a transparent inorganic material such as antimony tin oxide (ATO), indium tin oxide (ITO), indium zinc oxide (IZO), niobium oxide (NbOx), zinc oxide (ZnOx), gallium oxide (GaOx), tin oxide (SnOx), indium oxide (InOx), etc.

In example embodiments, the donor substrate 400 may include the antistatic member having the transparent conductive layer 450. The transparent conductive layer 450 for transmitting the laser beam may be disposed on one side of the base substrate 410. Thus, the donor substrate 400 may effectively prevent or may considerably reduce a static electricity generated in forming organic layer patterns on a display substrate of an organic light emitting display device. As a result, costs for manufacturing the organic light emitting display device may be reduced without an additional antistatic device, and the organic layer patterns may be uniformly formed on the display substrate.

FIGS. 5 to 7 are cross-sectional views illustrating a method of manufacturing an organic light emitting display device in accordance with example embodiments. In the method of manufacturing the organic light emitting display device illustrated in FIGS. 5 to 7, a donor substrate having a construction that is substantially the same as or substantially similar to the donor substrate 100 described with reference to FIG. 1, may be used. However, an organic light emitting display device having a construction that is substantially the same as or substantially similar to that of the organic light emitting display device obtained by the method illustrated in FIGS. 5 to 7 may be manufactured using one of the donor substrates 200, 300, and 400 described with reference to FIGS. 2 to 4.

Referring to FIG. 5, a donor substrate having a construction that is substantially the same as or substantially similar to that of the donor substrate 100 described with reference to FIG. 1 may be attached to a display substrate of the organic light emitting display device.

In example embodiments, the display substrate may include a transistor formed on a substrate 510, a first insulating interlayer 550, a second insulating interlayer 555, a first electrode 560, a pixel defining layer 570, etc.

A semiconductor pattern 520 may be formed on the substrate 510 having a transparent insulation material. The semiconductor pattern 520 may include a channel region 521, a source region 523, and a drain region 525. The semiconductor pattern 520 may be formed using amorphous silicon, amorphous silicon containing impurities, partially crystallized silicon, silicon containing micro crystals, etc. The source region 523 and the drain region 525 may be formed by implanting impurities to lateral portions of the semiconductor pattern 520, and thus the channel region 521 may be defined in accordance with formations of the source region 523 and the drain region 525.

A gate insulation layer 530 may be formed on the substrate 510 to cover the semiconductor pattern 520. A gate electrode 541 may be formed on the gate insulation layer 530. The gate insulation layer 530 may be formed using a silicon compound, a metal oxide, etc. The gate electrode 541 may be formed using a metal, an alloy, a metal nitride, a conductive metal oxide, etc. The gate electrode 541 may be disposed on a portion of the gate insulation layer 530 where the channel region 521 is located.

The first insulating interlayer 550 may be formed on the gate insulation layer 530 to cover the gate electrode 541. The first insulating interlayer 550 may be formed using silicon compound. A source electrode 543 and a drain electrode 545 may pass through the first insulating interlayer 550 to make contact with the source region 523 and the drain region 525, respectively. Thus, a switching device such as a thin film transistor (TFT) having the semiconductor pattern 520, the gate insulation layer 530, the gate electrode 541, the source electrode 543, and the drain electrode 545 may be provided on the substrate 510. Each of the source and the drain electrodes 543 and 545 may be formed using a metal, an alloy, a metal nitride, a conductive metal oxide, etc.

The second insulating interlayer 555 may be formed on the first insulating interlayer 550 to cover the source and the drain electrodes 543 and 545. The second insulating interlayer 555 may be formed using a transparent organic insulation material. The second insulating interlayer 555 may have a substantially level upper side on which elements of the organic light emitting display device are successively formed on the second insulating interlayer 555.

The first electrode 560 may be formed on the second insulating interlayer 555. The first electrode 560 may pass through the second insulating interlayer 555 to make contact with the drain electrode 545. The first electrode 560 may serve as a pixel electrode of the organic light emitting display device. According to an emission type of the organic light emitting display device, the first electrode 560 may be formed using a reflective material or a transparent conductive material.

The pixel defining layer 570 may be formed on a portion of the first electrode 560. The pixel defining layer 570 may be formed using an organic material or an inorganic material. A luminescent region I of the organic light emitting display device may be defined by the pixel defining layer 570. That is, a portion of the first electrode 560 exposed by the pixel defining layer 570 may be defined as the luminescent region I.

Referring to FIG. 5, the donor substrate may be arranged relative to the display substrate, wherein the organic transfer layer 140 of the donor substrate may make contact with the pixel defining layer 570 of the display substrate. In this case, the pixel defining layer 570 may protrude over the first electrode 560, so that the organic transfer layer 140 and the first electrode 560 may be spaced apart from each other by a first distance (D1). For example, when the pixel defining layer 570 has a thickness about 1 μm, the first distance D1 between the organic transfer layer 140 and the first electrode 560 may be about 1 μm.

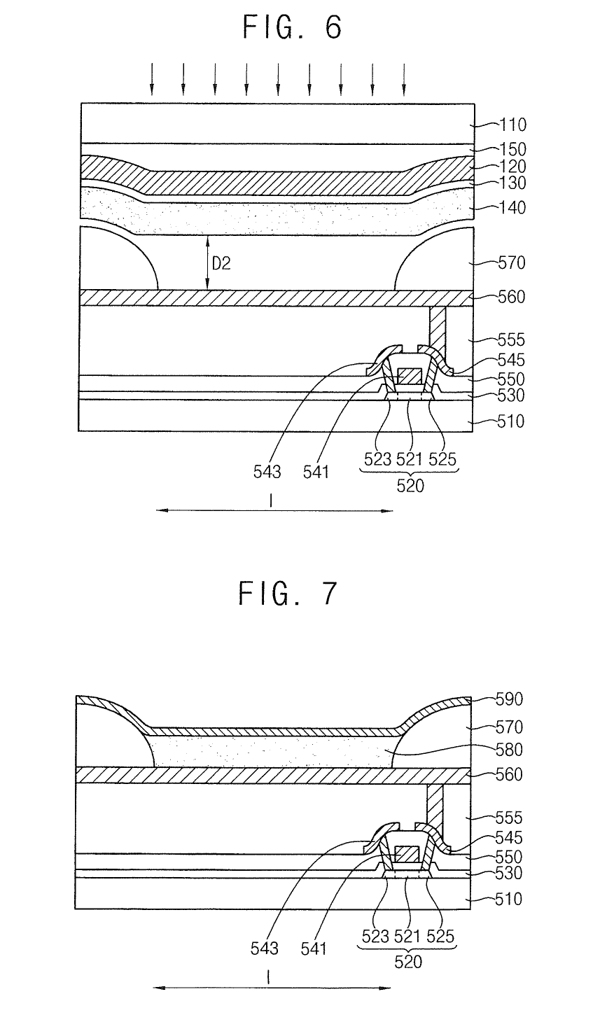

Referring to FIG. 6, a laser beam may be irradiated onto the donor substrate positioned over the luminescent region I of the display substrate. In this case, energy of the laser beam may be absorbed by the light-to-heat conversion layer 120 to be converted to heat or thermal energy, so that the organic transfer layer 140 may be transferred onto the first electrode 560 at the luminescent region I. When the donor substrate includes the expansion layer 150, a portion of the expansion layer 150 may expand by the heat or the thermal energy provided from the light-to-heat conversion layer 120. For example, the expansion layer 150 including a thermoplastic resin having a relatively large thermal expansion coefficient may partially expand at the luminescent region I, such that a thickness of a portion of the expansion layer 150 may increase. The first distance D1 between the organic transfer layer 140 and the first electrode 560 may be reduced by the increased thickness of the expansion layer 150. Hence, an interval between the organic transfer layer 140 and the first electrode 560 may be reduced as a second distance (D2) from the first distance (D1). Because the second distance (D2) may be substantially smaller than the first distance (D1), the organic transfer layer 140 may be effectively transferred onto the first electrode 560 even though a laser beam having a substantially small energy may be irradiated onto the donor substrate. In accordance with a thermal expansion coefficient of the expansion layer 150, a thickness of the expansion layer 150, and/or a thickness of the pixel defining layer 570, a distance between the organic transfer layer 140 and the first electrode 560 may be adjusted to thereby improve a transfer efficiency of the organic transfer layer 140. In some example embodiments, when the donor substrate includes an antistatic member having an antistatic agent, an antistatic layer, and/or a transparent conductive layer, the donor substrate may efficiently prevent or may considerably reduce static electricity generated during transferring the organic transfer layer 140, so that the organic transfer layer 140 may be uniformly transferred onto the first electrode 560.

Referring to FIG. 7, the donor substrate may be separated from the display substrate to obtain an organic layer pattern 580 on the first electrode 560 and a sidewall of the pixel defining layer 570 at the luminescent region I of the organic light emitting display device.

After forming a second electrode 590 on the pixel defining layer 570 and the organic layer pattern 580, a protection layer (not illustrated) and/or an upper substrate (not illustrated) may be disposed on the second electrode 590 to manufacture the organic light emitting display device. The second electrode 590 may be formed using a reflective material or a transparent conductive material in accordance with an emission type of the organic light emitting display device.

In a method of manufacturing the organic light emitting display device according to example embodiments, the organic layer pattern 580 may be formed using the donor substrate having the expansion layer 150. A thickness of a portion of the expansion layer 150 may increase under a portion of the organic transfer layer 140 to be transferred onto the first electrode 560, so that a distance between the organic transfer layer 140 and the first electrode 560 may decrease. Therefore, the organic transfer layer 140 may be effectively separated from the donor substrate. Additionally, the organic transfer layer 140 may be easily transferred by a laser beam having relatively small energy, such that the organic layer pattern 580 may be efficiently formed on the first electrode 560. Furthermore, the donor substrate may include the antistatic member having the antistatic agent, the antistatic layer, and/or the transparent conductive layer so that the donor substrate may effectively prevent or may greatly reduce a generation of static electricity while transferring the organic transfer layer 140 onto the substrate 510. Thus, the organic layer pattern 580 may be uniformly formed on the substrate 510 from the organic transfer layer 140 of the donor substrate. As a result, light emitting characteristics of the organic light emitting layer may be improved, and thus quality of an image displayed by the organic light emitting display device may be increased.

In example embodiments, a donor substrate may have an expansion layer, an antistatic agent, an antistatic layer, and/or a transparent conductive layer, so that organic layer patterns may be uniformly formed on a display substrate from an organic transfer layer of a donor substrate to thereby ensure improved light emitting characteristics of the organic layer patterns. An organic light emitting display device having the organic layer patterns may display an improved image, so that the organic light emitting display device may be employed in a high definition (HD) television, a smart cellular phone, a recent mobile communication device, etc.

The foregoing is illustrative of example embodiments and is not to be construed as limiting the present invention. Although a few example embodiments have been described, those skilled in the art will readily appreciate that many modifications are possible in the example embodiments without materially departing from the novel teachings and aspects of the invention. Accordingly, all such modifications are intended to be included within the scope of the invention as defined in the claims and their equivalents.

What is claimed is:

1. A donor substrate comprising:
a base substrate;
an expansion layer on the base substrate;
a light-to-heat conversion layer on the expansion layer;
an insulation layer on the light-to-heat conversion layer; and
an organic transfer layer on the insulation layer.

2. The donor substrate of claim 1, wherein the expansion layer comprises a material having a thermal expansion coefficient equal to or greater than about 1.5×10⁻⁵/° C.

3. The donor substrate of claim 2, wherein the expansion layer comprises a thermoplastic resin.

4. The donor substrate of claim 3, wherein the expansion layer comprises at least one selected from the group consisting of polystyrene, polymethyl acrylate, polyethyl acrylate, polypropyl acrylate, polyisopropyl acrylate, poly n-butyl acrylate, poly sec-butyl acrylate, poly isobutyl acrylate, poly tetra-butyl acrylate, polymethyl methacrylate, polyethyl methacrylate, poly n-butyl methacrylate, poly n-decyl methacrylate, polyvinyl chloride, polyvinylidene chloride, and acrylonitrile-butadiene-styrene copolymer.

5. The donor substrate of claim 3, wherein the base substrate comprises a thermoplastic resin, and the base substrate and the expansion layer are integrally formed.

6. A donor substrate comprising:
a base substrate;
a light-to-heat conversion layer on a first side of the base substrate;
an insulation layer on the light-to-heat conversion layer;
an organic transfer layer on the insulation layer; and
an antistatic member in the base substrate or the insulation layer.

7. The donor substrate of claim 6, wherein the antistatic member comprises an antistatic agent dispersed in the base substrate.

8. The donor substrate of claim 7, wherein the antistatic agent has a concentration between about 0.1 percent by weight and about 0.2 percent by weight based on a total weight of the base substrate.

9. The donor substrate of claim 7, wherein the antistatic agent comprises at least one selected from the group consisting of a glycerin monomer stearate-based antistatic material, an amine-based antistatic material, and a magnetic metal oxide.

10. The donor substrate of claim 6, wherein the antistatic member comprises an antistatic agent dispersed in the insulation layer.

11. The donor substrate of claim 6, wherein the antistatic member comprises a transparent conductive layer on a second side of the base substrate.

12. The donor substrate of claim 11, wherein the transparent conductive layer comprises a conductive metal oxide or a high molecular weight conductive material.

13. The donor substrate of claim 12, wherein the transparent conductive layer comprises at least one selected from the group consisting of polyaniline, polypyrrole, polythiophene, polyethylenedioxythiophene, antimony tin oxide, indium tin oxide, indium zinc oxide, niobium oxide, zinc oxide, gallium oxide, tin oxide, and indium oxide.

14. A method of forming a donor substrate, comprising:
forming a base substrate;
forming an expansion layer on the base substrate;
forming a light-to-heat conversion layer on the expansion layer;
forming an insulation layer on the light-to-heat conversion layer; and
forming an organic transfer layer on the insulation layer.

15. The method of claim 14, wherein the expansion layer is formed by coating a thermoplastic resin on the base substrate by a spin coating process, a slit coating process, or a gravure coating process.

16. The method of claim 14, wherein the expansion layer is formed using a polyethylene terephthalate resin containing a thermoplastic resin.

17. The method of claim 16, wherein the expansion layer is formed by a biaxial drawing process.

18. A method of forming a donor substrate, comprising:
forming a base substrate;
forming a light-to-heat conversion layer on a first side of the base substrate;
forming an insulation layer on the light-to-heat conversion layer;
forming an organic transfer layer on the insulation layer; and
forming an antistatic member in the base substrate, in the insulation layer, or on a second side of the base substrate.

19. The method of claim 18, wherein the forming the antistatic member comprises dispersing an antistatic agent in the base substrate.

20. The method of claim 18, wherein the forming the antistatic member comprises dispersing an antistatic agent in the insulation layer.

21. The method of claim 18, wherein the forming the antistatic member comprises forming a transparent conductive layer on the second side of the base substrate.

22. A method of manufacturing an organic light emitting display device, comprising:
forming a lower electrode on a substrate;
forming a pixel defining layer on the lower electrode to define a pixel region;
forming a donor substrate including a base substrate, an expansion layer on the base substrate, a light-to-heat conversion layer on the expansion layer, and an organic transfer layer on the light-to-heat conversion layer;
attaching the donor substrate to the substrate with the organic transfer layer facing the pixel region of the substrate; and
forming an organic layer pattern on the pixel region from the organic transfer layer by irradiating a laser beam onto at least a portion of the donor substrate opposite the pixel region.

23. The method of claim 22, wherein the donor substrate further comprises an insulation layer between the light-to-heat conversion layer and the organic transfer layer.

24. A method of manufacturing an organic light emitting display device, comprising:
forming a lower electrode on a substrate;
forming a pixel defining layer on the lower electrode to define a pixel region;
forming a donor substrate including a base substrate, a light-to-heat conversion layer on a first side of the base substrate, an insulation layer on the light-to-heat conversion layer, an organic transfer layer on the insulation layer, and an antistatic member in the base substrate, in the insulation layer, or on a second side of the base substrate;
attaching the donor substrate to the substrate with the organic transfer layer facing the pixel region of the substrate; and
forming an organic layer pattern on the pixel region from the organic transfer layer by irradiating a laser beam onto at least a portion of the donor substrate opposite the pixel region.

25. The method of claim 24, wherein the antistatic member comprises an antistatic agent dispersed in the insulation layer.

26. The method of claim 24, wherein the antistatic member comprises an antistatic agent dispersed in the base substrate.
